(19) United States
(12) Patent Application Publication
(10) Pub. No.: US 2013/0021101 A1
(43) Pub. Date: Jan. 24, 2013

(54) DIFFERENTIAL AMPLIFIER HAVING RAIL-TO-RAIL INPUT VOLTAGE RANGE

(71) Applicant: Alexander Frey, Augsburg (DE)

(72) Inventor: Alexander Frey, Augsburg (DE)

(21) Appl. No.: 13/639,798

(22) PCT Filed: Mar. 25, 2011
(86) PCT No.: PCT/EP2011/054588

§ 371 Date: Oct. 5, 2012

(30) Foreign Application Priority Data
Apr. 6, 2010 (DE) 102010013958.0

(51) Int. Cl. H03F 3/45

(52) U.S. Cl. 330/257; 330/253

(57) ABSTRACT

A differential amplifier having a rail-to-rail input voltage range, includes a first differential input stage, which is connected to a first supply voltage rail via a first power source and a second complementary differential input stage, which is connected to the second supply voltage rail via a second power source. To this end, switching device are provided, which deactivate the first differential input stage and activate the second differential input stage when the voltage value of the input voltage signal exceeds a predetermined first voltage threshold in the event of rising input voltage, and which deactivate the second differential input stage and activate the first differential input sage when the voltage value of the input voltage signal falls below a predetermined second voltage threshold in the event of falling input voltage. A constant input slope can thus be achieved, having a high phase reserve, which makes the device particularly applicable in the field of biosensory technology.

### CROSS REFERENCE TO RELATED APPLICATIONS

This application is the U.S. national stage of International Application No. PCT/EP2011/054588, filed Mar. 25, 2011 and claims the benefit thereof. The International Application claims the benefits of German Application No. 102010013958.0 filed on Apr. 6, 2010, both applications are incorporated by reference herein in their entirety.

### BACKGROUND

The invention relates to a differential amplifier having a rail-to-rail input voltage range.

Differential amplifiers represent an important class of basic circuit blocks for implementing analog circuits. Differential amplifiers are usually designed using CMOS (Complementary Metal Oxide Semiconductor) or bipolar technology as operational or transconductance amplifiers. The properties are specified by way of various parameters, such as power consumption, bandwidth, amplification, noise properties, etc. Another special property of differential amplifiers is the input voltage range which can be processed by the circuit in relation to the supply voltage of the circuit. Without special circuitry measures the input voltage range is typically lower than the supply voltage range.

There are application constellations, however, in which it is advantageous or very important to be able to process the entire voltage range, which is possible for a given technology, at the input side. A constellation of this kind arises for example in modern semiconductor processes which have only a low supply voltage. This requirement also emerges for older semiconductor processes which are operated with lower than nominal voltages for “low power” operation. Even in sensor technology it may occur that a sensor signal for processing exists in such a large range that a processing capacity over the entire input voltage range of a differential amplifier is required.

Differential amplifiers whose input voltage range matches the supply voltage range—conventionally called a “rail-to-rail” differential amplifier—are basically known.

FIG. 1 illustrates the basic problem in the implementation of a rail-to-rail input voltage range using the example of differential input stages of a differential amplifier using conventional CMOS circuitry. The related art and the inventor's proposals will always be illustrated below with the aid of an implementation using CMOS technology. An implementation using bipolar technology is analogously possible as well, however.

The left-hand part of FIG. 1 schematically shows an implementation of a differential input stage 1 having a pair of n-MOS transistors 2a and 2b, connected in parallel, which are connected by a current source 3 to a supply voltage rail 4, which carries a low supply voltage VSS. This circuit arrangement allows high voltage levels, in particular in the range of a high level VDD of the supply voltage as well, to be processed. For low voltage levels, in particular in the range of the low level VSS of the supply voltage, the circuit arrangement is not functional, however, since the control voltage at the control connections of the transistors 2a and 2b are no longer adequate for operating the transistors 2a and 2b in the required analog operating point.

As an alternative to this, as is schematically shown in the right-hand part of FIG. 1, an input differential stage 1′ having a pair of p-MOS transistors 2a′ and 2b′, connected in parallel, can be implemented, which are connected by a current source 3′ to a supply voltage rail 5, which carries the high supply voltage VDD. Complementary conditions result in this connection, however. This, the circuit arrangement allows low voltage levels to be processed, in particular in the range of the low level VSS of the supply voltage as well, but does not work for high voltage levels, in particular in the range of the high level VDD of the supply voltage.

The supply voltage rails are often also called “rails”, and this clarifies the description “rail-to-rail”.

The basically known approach to implementing a rail-to-rail input voltage range accordingly lies in a parallel circuit of the circuit arrangements illustrated with the aid of FIG. 1. Input levels in the range of the low level VSS of the supply voltage are processed by the p-MOS pair of transistors, whereas input levels in the range of the high level VDD of the supply voltage are processed by the n-MOS pair of transistors. Medium levels can in principle be processed by both input stages depending on the specific design.

A central task of a differential input stage is the provision of a desired input slope or transconductance gm which represents what is known as a small signal parameter. An input voltage signal is converted into a current signal which, via a load element, is then converted back into an amplified voltage signal in an output stage of the differential amplifier. The input slope gm is crucially important for basic switching properties, such as amplification or control stability. The control and dimensioning of this parameter is accordingly of crucial importance in the design process. A desired, optimally constant value for the input slope gm is conventionally adjusted by way of bias conditions in a suitable working point. For rail-to-rail differential amplifiers this occurs separately for the n-MOS branch and the p-MOS branch.

FIG. 2 shows a specific example of a conventional implementation of a rail-to-rail differential amplifier according to the principle of “constant input slope gm by regulating bias currents”. A circuit arrangement of this type is known by way of example from the documents J. H. Huijsing et al, “Low-voltage operational amplifier with rail-to-rail input and output ranges”, IEEE J. Solid State Circuits, vol. 20, no. 6, pages 1144-1150, 1985 and M. Augustyniak et al, “A 24×16 CMOS-based chronocoloumetric and microarray”, Tech Dig. ISSCC, pages 59-68, 2006.

Transistors T11, T12, T13 and T14, which are designed by way of example as MOSFETs (metal oxide semiconductor field-effect transistor), are wired in a known manner in such a way that they form complementary differential input stages of a conventional rail-to-rail differential amplifier. A first differential input stage 11-P (p-differential input stage) formed from the transistors T11 and T12 is supplied with a first bias current Ip by a first current source 12-P via a first current mirror 13-P, which is implemented by transistors T21 and T22. The first current source 12-P is connected to a first supply voltage rail (not shown) and this carries a high supply voltage VDD. A second differential input stage 11-N (n-differential input stage) formed from the transistors T13 and T14 is similarly supplied with a second bias current In by a second current source 12-N via a second current mirror 13-N. A replica p-differential input stage 15, which is formed from transistors T15 and T16 and which exactly replicates the first differential input stage 11-P formed from the transistors T21 and T22, is supplied with the first bias current Ip by a third current mirror 14, which is formed by the transistor T21 in connection with a transistor T23. The second current source 12-P is connected to a second supply voltage rail (not shown) and this carries a low supply voltage VSS. The replica p-differential input stage 15 is connected to the control connections of the transistors T31 and T32 by a fourth current mirror 16 formed from transistors T41 and T42.

This circuit arrangement means that for input voltages beginning with the low level VSS of the supply voltage, the circuit is initially operated solely via the first differential input stage 11-P. The second differential input stage 11-N is deactivated since the second bias current In discharges across the transistor T41. This is achieved by way of suitable dimensioning of the current mirror chain T21, T23, T42 and T41. For increasing values of the input voltage the transistor T22 is driven from its saturation range and the current and therewith the input slope gm is also reduced. This process is replicated as it were by the replica p-differential input stage 15 in connection with the transistor T23. The decreasing current in the replica p-differential input stage 15 leads across the transistor T42 to a decreasing control current at transistor T41, and this in turn means that less bias current In from the second differential input stage 11-N discharges across the transistor T41 and more bias current is thereby available for operation of the second differential input stage 11-N. The circuit arrangement according to FIG. 2 is therewith based on the principle of compensating the decreasing input slope gm in the first differential input stage 11-P by way of an increasing input slope in the second differential input stage 11-N.

One drawback in this connection is that relatively complex circuitry is required for this purpose, the replica p-differential input stage in particular also having a large area requirement which also leads to high costs. The circuit arrangement according to FIG. 2 also leads to a characteristic of the input slope gm over the input voltage, as is shown in FIG. 3. It may clearly be seen therein that, in a transition region between operation of the first differential input stage 11-P and the second differential input stage 11-N, in the illustrated example in a range between about 2 and 2.5 volts, a clear overshoot results in the input slope which is very disadvantageous, for example with respect to control stability.

This effect may also be seen in FIG. 4 which shows the phase reserve crucial to control stability as a function of the input voltage for the nominal case tm (typical mean) which is shown in bold, and for some so-called “corner cases” which differ from the nominal case. High control stability may only be ensured by way of a high phase reserve. In general phase reserves up to about 70° are regarded as being acceptable. In some applications, such as in control circuits for the operation of electrochemical reactions, the aim is a phase reserve which is as high as possible. FIG. 4 shows that the phase reserve of the circuit arrangement according to FIG. 2 drops in the transition region between operation of the first differential input stage 1-P and the second differential input stage 1-N, i.e. between about 2 and 2.5 volts, to values of up to 65°.

### SUMMARY

One potential object is to create a differential amplifier having a rail-to-rail input voltage range which with simple circuitry ensures an optimally constant input slope over the entire input voltage range.

The inventor proposes a differential amplifier having a rail-to-rail input voltage range, having
a first supply voltage rail,
a second supply voltage rail which carries a voltage which is less than the voltage on the first supply voltage rail,
a first differential input stage for amplifying a differential input voltage signal, which comprises a pair of first transistors which are connected to the first voltage supply rail by a first current source,
a second differential input stage for amplifying the differential input voltage signal, which comprises a pair of second transistors, complementary to the first transistors, which is connected to the second supply voltage rail by a second current source, and
a switching device, which deactivate the first differential input stage and activate the second differential input stage if the voltage value of the input voltage signal exceeds a predetermined first voltage threshold in the event of rising input voltage, and which deactivate the second differential input stage and activate the first differential input stage if the voltage value of the input voltage signal falls below a predetermined second voltage threshold, which lies above the first voltage threshold, in the event of falling input voltage.

According to the proposal, in contrast to the approaches known from the related art, there is no continuous transition from a differential input stage to the complementary differential input stage, and instead an “erratic” switchover is made when a predefined voltage threshold is reached. An undesirable overshoot of the input slope in the region of the change in processing from one differential input stage to the other is avoided in this way, and this also contributes to an improvement in the circuit performance with respect to phase reserve and amplification.

According to one embodiment the switching device comprises a first controllable switching element, which is connected between the first current source and the first supply voltage rail, a second controllable switching element, which is connected between the second current source and the second supply voltage rail, and a hysteresis-afflicted comparator whose output is connected to the control inputs of the first and second switching elements. The switching elements are advantageously designed as transistors.

The use of a hysteresis-afflicted comparator—frequently also called a Schmitt trigger
which controls switching elements, in particular in the form of transistors, represents a particularly simple implementation in terms of circuitry, which leads to a considerable reduction in area and therewith to a clear cost saving compared with conventional circuit arrangements.

One embodiment provides that the comparator comprises adjustable voltage thresholds. As a result the differential amplifier can be adapted to specific requirements of different specific applications and can therewith be universally employed.

According to a further embodiment the input of the comparator is connected to a positive voltage input of the differential input stages, and this leads to a further simplification of the circuit topology.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 shows a schematic diagram of an n-MOS and a p-MOS differential input stage of a differential amplifier according to the related art,

FIG. 2 shows a schematic diagram of a rail-to-rail differential amplifier according to the related art,

FIG. 3 shows a graph of the input slope as a function of the input voltage for the differential amplifier according to FIG. 2,

FIG. 4 shows a graph of the phase reserve as a function of the input voltage for the differential amplifier according to FIG. 2,

FIG. 5 shows a schematic diagram of a rail-to-rail differential amplifier proposed by the inventor,

FIG. 6 shows a graph of the input slope as a function of the input voltage when the n-MOS branch and the p-MOS branch are considered separately,

FIG. 7 shows a graph of the phase reserve as a function of the input voltage for the differential amplifier according to FIG. 5.

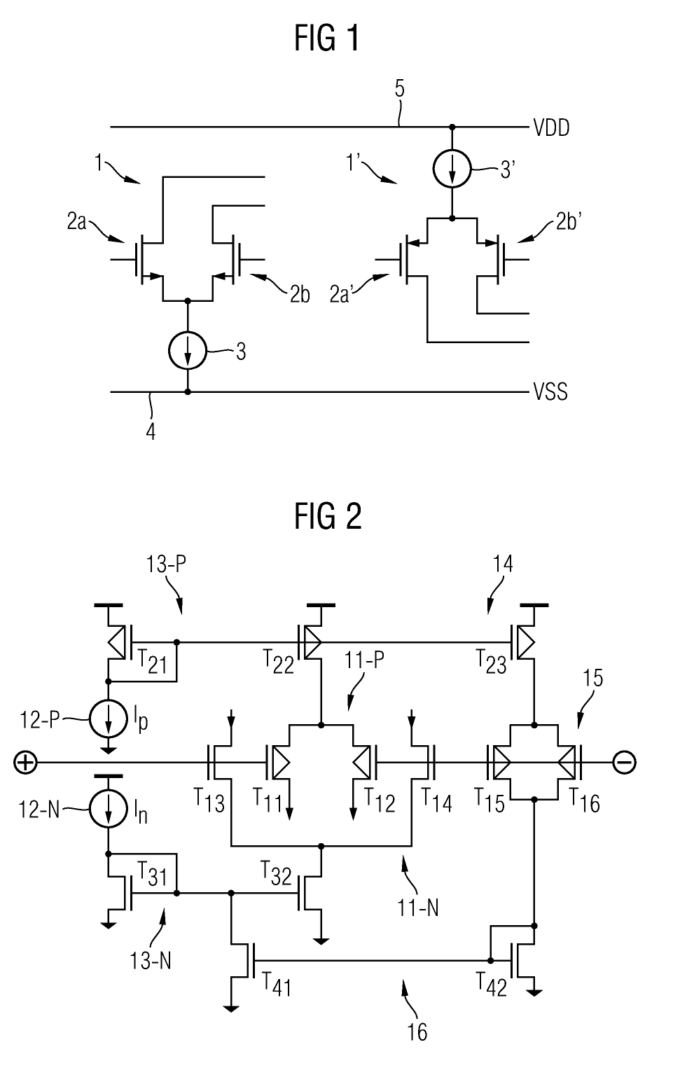

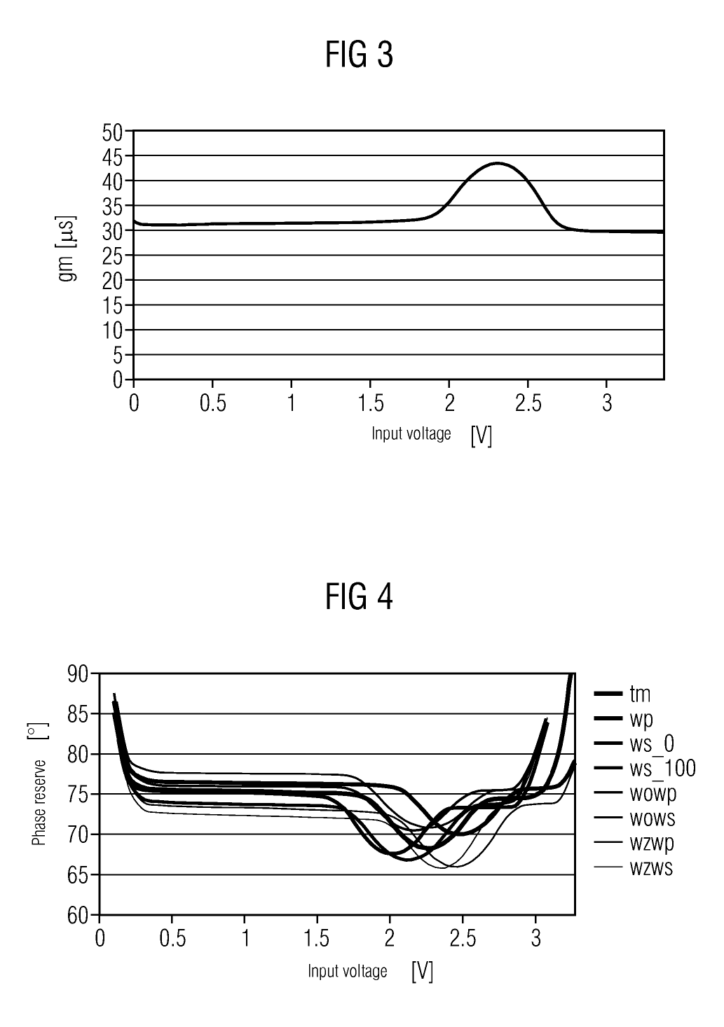

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

The rail-to-rail differential amplifier schematically illustrated in FIG. 5 differs from the differential amplifier illustrated in FIG. 2 in that the additional wiring with the transistors T23, T41 and T42 and the replica p-differential input stage 5 have been omitted. Instead a switching device 50 is provided which comprises a first controllable switching element 51 in the form of a transistor T51, a second controllable switching element 52 in the form of a transistor T52 and a hysteresis-afflicted comparator 53. The first switching element 51 is connected between the first current source 12-P and the first supply voltage rail (not shown) and the second switching element 52 is connected between the second current source 12-N and the second supply voltage rail (not shown). The output of the comparator 53 is connected to the control inputs of the first and second switching element 51 or 52. The input of the comparator 53 is connected to the positive voltage input “+” of the differential input stages. A switchover point, at which a switchover is made from one differential input stage to the respective complementary differential input stage, is defined by voltage thresholds or hysteresis levels Llow and Vhigh of the comparator 53, which are advantageously adjustable but can also be permanently set. The first differential input stage 11-P is thus deactivated and the second differential input stage 11-N is activated if the voltage value of the input voltage signal exceeds the predetermined first voltage threshold Vlow in the event of rising input voltage, and the second differential input stage 11-N is deactivated and the first differential input stage 11-P is activated if the voltage value of the input voltage signal falls below the predetermined second voltage value Vhigh in the event of falling input voltage, where Vhigh is above Vlow.

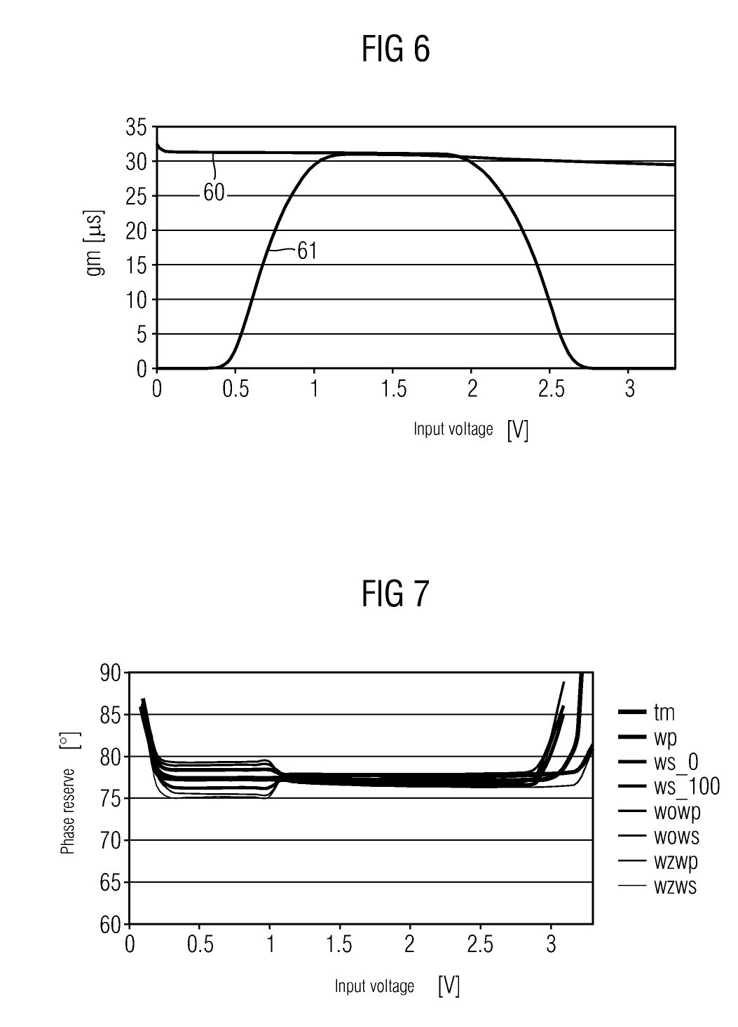

FIG. 6 shows the input slope as a function of the input voltage when the two complementary differential input stages 11-P and 11-N are considered separately. Characteristic curve 60 shows the course for the p-MOS branch and characteristic curve 61 shows the course for the n-MOS branch. If the switchover is made in a voltage range in which the two differential input stages 11-P and 11-N have similar values, i.e. in a range between about 1 volt and 2 volts in the illustrated example, an almost constant input slope gm is thus achieved which does not exhibit a disadvantageous overshoot even in the transition region.

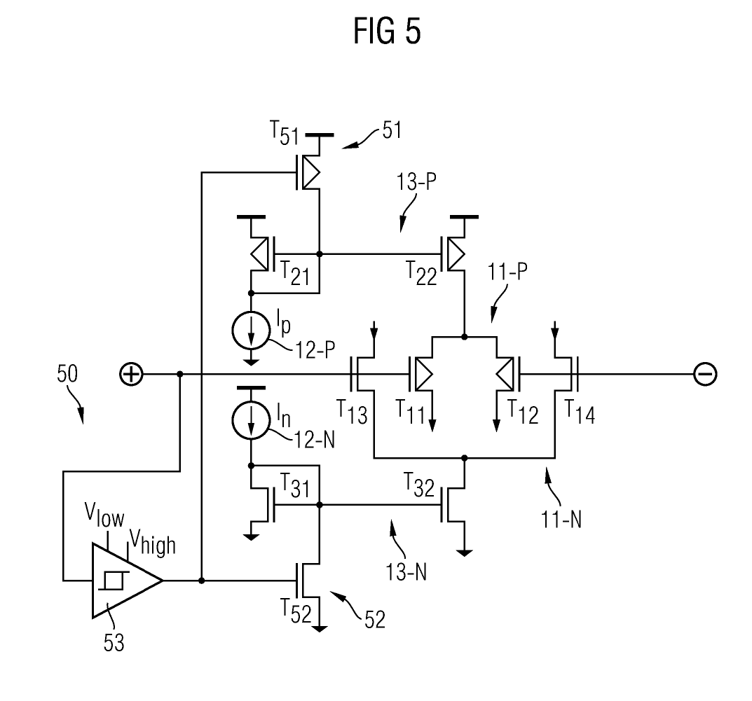

Furthermore, compared with the related art, the phase reserve also exhibits a much improved course (cf. FIG. 7). The nominal case tm (typical mean), which is shown in bold, and some so-called “corner cases”, which differ from the nominal case, are also shown again here. Whereas in the case of the circuit arrangement according to the related art a drop of about 10° (75° to 65°, cf. FIG. 4) results, based on the nominal value of the phase reserve, the drop can be limited to 2° (77° to 75°) for the circuit arrangement. The differential amplifier consequently has much improved control stability.

Due to the omission of current paths the simplified circuitry compared with the related art also leads to a power saving, and the omission of the replica differential input stage in particular leads to a clear reduction in area and therewith cost.

The system also includes permanent or removable storage, such as magnetic and optical discs, RAM, ROM, etc. on which the process and data structures of the present invention can be stored and distributed. The processes can also be distributed via, for example, downloading over a network such as the Internet. The system can output the results to a display device, printer, readily accessible memory or another computer on a network.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-6. (canceled)

7. A differential amplifier having a rail-to-rail input voltage range, comprising
a first supply voltage rail;
a second supply voltage rail which carries a voltage less than the voltage on the first supply voltage rail;
a first differential input stage amplifying a differential input voltage signal, which includes a pair of first transistors which are connected to the first voltage supply rail by a first current source;
a second differential input stage amplifying the differential input voltage signal, which comprises a pair of second transistors, complementary to the first transistors, which is connected to the second supply voltage rail by a second current source; and
a switch which deactivates the first differential input stage and activates the second differential input stage if the voltage value of the input voltage signal exceeds a predetermined first voltage threshold in the event of rising input voltage, and which deactivates the second differential input stage and activates the first differential input stage if the voltage value of the input voltage signal falls below a predetermined second voltage threshold, which lies above the first voltage threshold, in the event of falling input voltage.

8. The differential amplifier as claimed in claim 7, wherein a respective current mirror is provided between the current source and the supply voltage rail.

9. The differential amplifier as claimed in claim 8, wherein the switch comprises
a first controllable switching element connected between the first current source and the first supply voltage rail,
a second controllable switching element connected between the second voltage source and the second supply voltage rail, and
a hysteresis-afflicted comparator having an output connected to the control inputs of the first and second switching elements.

10. The differential amplifier as claimed in claim 9, wherein the comparator uses adjustable voltage thresholds.

11. The differential amplifier as claimed in 10, wherein the controllable switching elements are transistors.

12. The differential amplifier as claimed in claim 11, wherein the input of the comparator is connected to a positive voltage input of the differential input stages.
